(19) United States
(12) Patent Application Publication
(10) Pub. No.: US 2026/0082627 A1
(43) Pub. Date: Mar. 19, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Tsuyoshi KACHI, Kanazawa Ishikawa (JP)

(21) Appl. No.: 18/977,268

(22) Filed: Dec. 11, 2024

(30) Foreign Application Priority Data
Sep. 13, 2024 (JP) 2024-159336

(51) Int. Cl. H10D 30/66; H10D 64/66; H10D 64/00

(52) U.S. Cl. CPC H10D 30/668; H10D 64/668; H10D 64/117

(57) ABSTRACT

A semiconductor device according to one embodiment, includes first and second electrodes, a semiconductor layer, a plurality of third electrodes, a fourth electrode, a first contact and a first conductive layer. The semiconductor layer is located between the first electrode and the second electrode. The semiconductor layer includes first to third semiconductor regions. The plurality of third electrodes faces the first semiconductor region via a first insulating part. The fourth electrode includes a part positioned between two mutually-adjacent third electrodes. The fourth electrode includes a first extension part and a wide part. The fourth electrode faces the second semiconductor region via a second insulating part. The first contact is positioned above the fourth electrode. The first contact is connected with the wide part. The first conductive layer is positioned above the fourth electrode. The first conductive layer is connected with the fourth electrode by the first contact.

This application is based upon and claims the benefit of priority from Japanese Patent Application No. 2024-159336, filed on September 13, 2024; the entire contents of which are incorporated herein by reference.

### FIELD

Embodiments relate to a semiconductor device.

### BACKGROUND

In a semiconductor device such as a power MOSFET (Metal-Oxide-Semiconductor Field-Effect Transistor) or similar devices that includes a transistor, reducing the gate resistance of the transistor can, for example, increase the switching speed.

### BRIEF DESCRIPTION OF THE DRAWINGS

FIG. 1 is a schematic plan view illustrating a semiconductor device according to an embodiment;

FIG. 2 is a schematic view illustrating the semiconductor device according to the embodiment;

FIG. 3 is a schematic view illustrating the semiconductor device according to the embodiment;

FIG. 4 is a schematic cross-sectional view illustrating the semiconductor device according to the embodiment;

FIG. 5 is a schematic view illustrating the semiconductor device according to the embodiment;

FIG. 6 is a schematic view illustrating a semiconductor device according to a modification of the embodiment;

FIG. 7 is a schematic view illustrating the semiconductor device according to the modification of the embodiment;

FIGS. 8A and 8B are schematic cross-sectional views illustrating the method for manufacturing the semiconductor device according to the embodiment;

FIGS. 9A and 9B are schematic cross-sectional views illustrating the method for manufacturing the semiconductor device according to the embodiment;

FIG. 10 is a schematic cross-sectional view illustrating the method for manufacturing the semiconductor device according to the embodiment;

FIG. 11 is a schematic view illustrating another semiconductor device according to the embodiment;

FIG. 12 is a schematic view illustrating another semiconductor device according to the embodiment;

FIG. 13 is a schematic cross-sectional view illustrating another semiconductor device according to the embodiment; and

FIG. 14 is a schematic view illustrating another semiconductor device according to the embodiment.

### DETAILED DESCRIPTION

A semiconductor device according to one embodiment, includes a first electrode, a second electrode, a semiconductor layer, a plurality of third electrodes, a fourth electrode, a first contact and a first conductive layer. The second electrode is positioned above the first electrode. The semiconductor layer is located between the first electrode and the second electrode. The semiconductor layer includes a first semiconductor region, a second semiconductor region, and a third semiconductor region. The first semiconductor region is of a first conductivity type. The second semiconductor region is located on the first semiconductor region. The second semiconductor region is of a second conductivity type. The third semiconductor region is located on the second semiconductor region. The third semiconductor region is electrically connected with the second electrode. The third semiconductor region is of the first conductivity type. The plurality of third electrodes is arranged in a cell region in which the second electrode is located. The plurality of third electrodes faces the first semiconductor region via a first insulating part. The fourth electrode includes a part positioned between two mutually-adjacent third electrodes among the plurality of third electrodes. The fourth electrode includes a first extension part and a wide part. The first extension part is positioned in the cell region. The wide part is positioned in the cell region and is wider than the first extension part. The fourth electrode faces the second semiconductor region via a second insulating part. The first contact is positioned above the fourth electrode. The first contact is connected with the wide part of the fourth electrode. The first conductive layer is positioned above the fourth electrode. The first conductive layer is connected with the fourth electrode by the first contact.

Various embodiments are described below with reference to the accompanying drawings.

The drawings are schematic and conceptual; the relationships between the thickness and width of portions, and the proportions of sizes among portions, are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

In the following description and drawings, the notations of n⁺ and n⁻ indicate relative levels of the impurity concentrations. In other words, a notation marked with "+" indicates that the impurity concentration is relatively greater than that of a notation not marked with either "+" or "-", and a notation marked with "-" indicates that the impurity concentration is relatively less than that of a notation without any mark. When both a p-type impurity and an n-type impurity are included in each region, these notations indicate relative levels of the net impurity concentrations after the impurities are compensated.

In the examples described below, a first conductivity type is the n-type, and a second conductivity type is the p-type. In the embodiments described below, each embodiment may be implemented by inverting the n-type and the p-type of each semiconductor region.

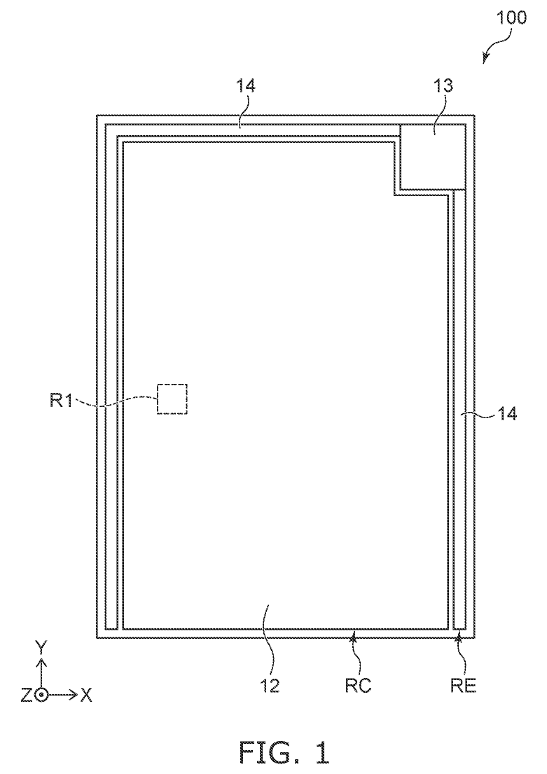

FIG. 1 is a schematic plan view illustrating a semiconductor device according to an embodiment.

In the description of the embodiments, an X-direction, a Y-direction, and a Z-direction that are orthogonal to each other are used. For example, when viewed from above (when viewed along the Z-direction) as illustrated in FIG. 1, the semiconductor device 100 according to the embodiment is a rectangle having sides extending in the X-direction and Y-direction.

The semiconductor device 100 is, for example, a MOSFET. A source electrode 12, a gate pad 13, and a gate wiring part 14 are located at the upper surface side of the semiconductor device 100. For example, the source electrode 12, the gate pad 13, and the gate wiring part 14 are arranged in the same X-Y plane.

In the semiconductor device 100, a cell region RC in which the source electrode 12 is located is set, and a peripheral region RE that is positioned at the periphery of the cell region RC in the X-Y plane is set. As described below, the cell region RC is a region in which transistors are formed in the semiconductor layer. The source electrode 12 extends in the X-Y plane and covers the entire cell region RC. The gate pad 13 and the gate wiring part 14 are not located in the cell region RC. The source electrode 12 is insulated from the gate pad 13 and the gate wiring part 14.

The peripheral region RE is arranged with the cell region RC in directions in the X-Y plane. The peripheral region RE may include, for example, a termination region of the semiconductor device 100. The termination region includes the outer edge of the semiconductor layer when viewed in plan and is a region along the outer edge. The gate wiring part 14 and the gate pad 13 are located in the peripheral region RE and may surround, for example, the source electrode 12. The gate wiring part 14 extends in the X-direction or Y-direction and is electrically connected with the gate pad 13. In the example, the gate pad 13 is located at a corner part of the rectangle of the semiconductor device 100. The source electrode 12 is not located in the peripheral region RE.

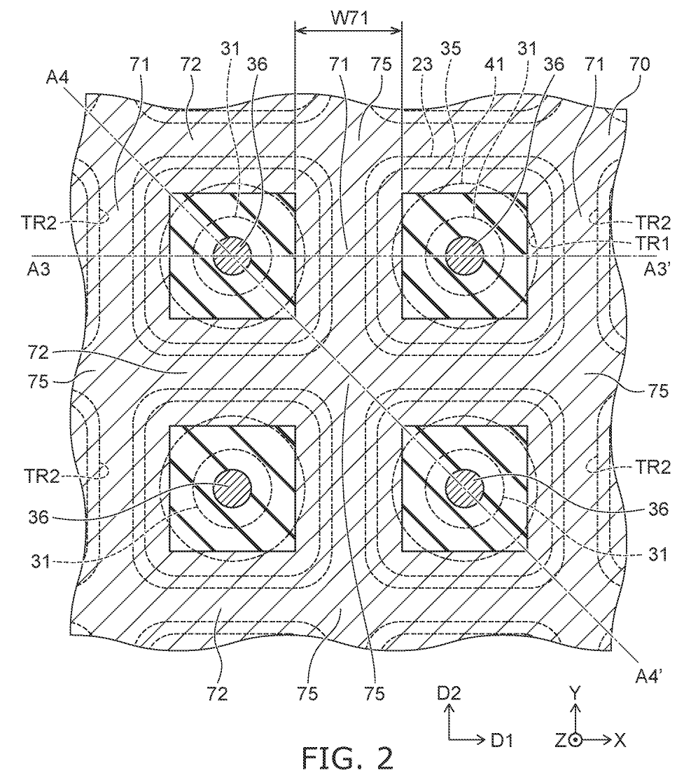

FIGS. 2 to 5 are schematic views illustrating the semiconductor device according to the embodiment.

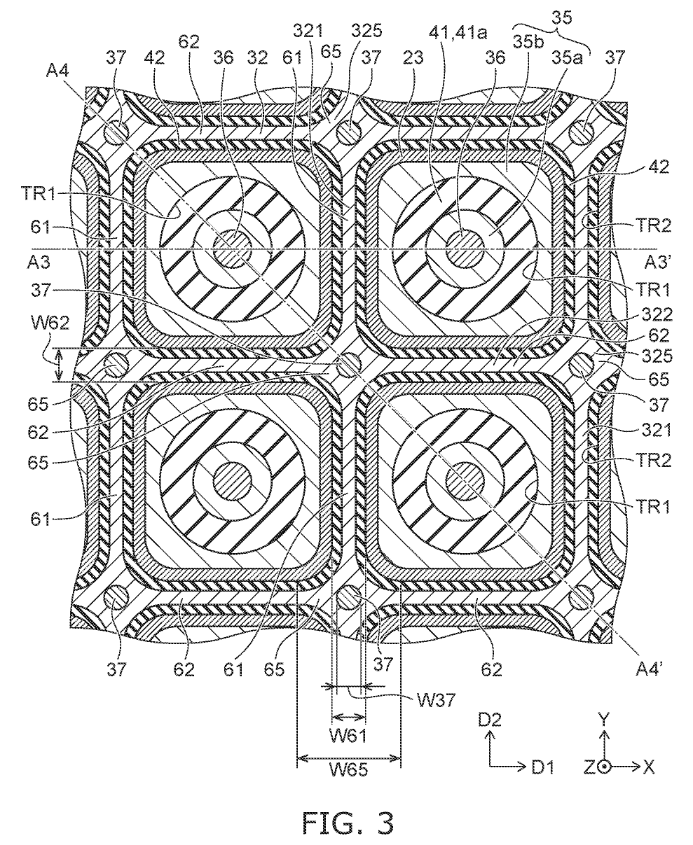

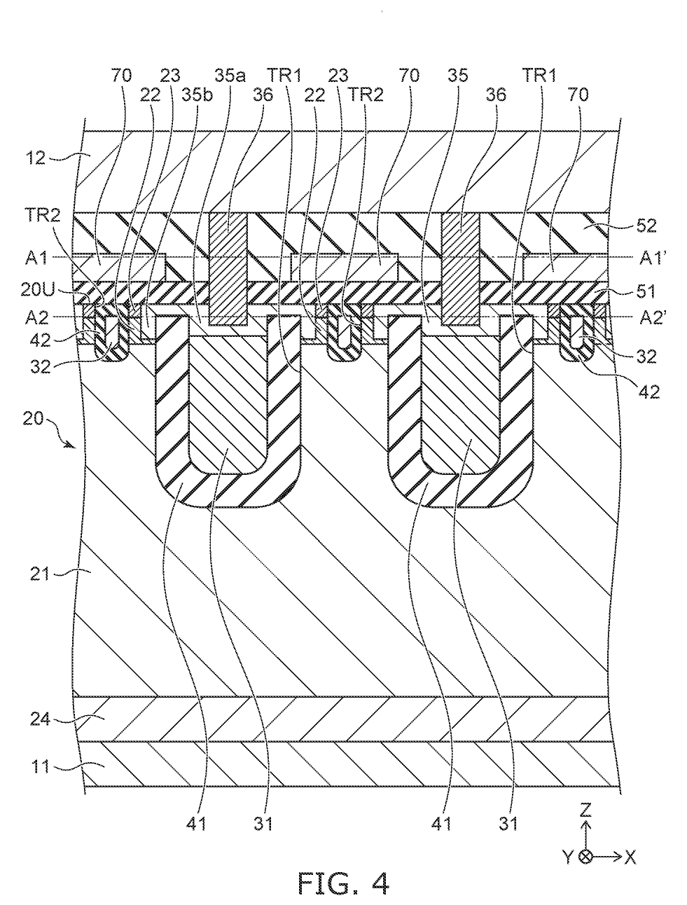

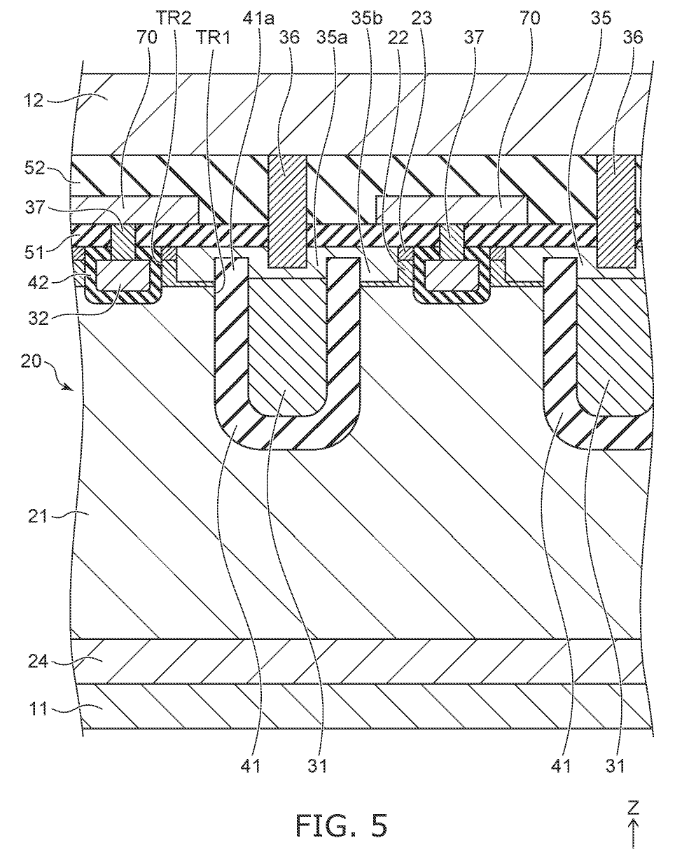

FIGS. 2 to 5 illustrate the structure inside the cell region RC (a region R1 illustrated in FIG. 1). FIGS. 2 and 3 illustrate the planar layout. The hatching of FIG. 2 corresponds to a cross section along line A1-A1ʹ shown in FIG. 4; and the hatching of FIG. 3 corresponds to a cross section along line A2-A2ʹ shown in FIG. 4. FIG. 4 illustrates a cross section along line A3-A3ʹ shown in FIGS. 2 and 3. FIG. 5 illustrates a cross section along line A4-A4ʹ shown in FIGS. 2 and 3.

For example, as illustrated in FIG. 4, the semiconductor device 100 includes a drain electrode 11 (a first electrode), the source electrode 12 (a second electrode), and a semiconductor layer 20. The semiconductor layer 20 is positioned between the drain electrode 11 and the source electrode 12.

In the description of the embodiments, the direction from the drain electrode 11 toward the source electrode 12 is taken as the Z-direction. The upper surface and lower surface of the semiconductor layer 20 (the semiconductor substrate) are along the X-Y plane perpendicular to the Z-direction. For convenience, the direction from the drain electrode 11 toward the source electrode 12 is called "up", and the opposite direction is called "down". These directions are based on the relative positional relationship between the drain electrode 11 and the source electrode 12, and are independent of the direction of gravity.

The semiconductor layer 20 includes a drain region 24, a drift region 21 (a first semiconductor region), a base region 22 (a second semiconductor region), and a source region 23 (a third semiconductor region).

The drain region 24 is a semiconductor region of a first conductivity type (the n⁺-type). The drain region 24 is located on the drain electrode 11 and electrically connected with the drain electrode 11.

The drift region 21 is a semiconductor region of the first conductivity type (the n⁻-type) located on the drain region 24. The n-type impurity concentration (atoms/cm³) in the drift region 21 is less than the n-type impurity concentration (atoms/cm³) in the drain region 24.

The base region 22 is a semiconductor region of a second conductivity type (the p-type) located on a portion of the drift region 21.

The source region 23 is a semiconductor region of the first conductivity type (the n⁺-type) located on a portion of the base region 22. The upper end of the source region 23 is positioned at an upper surface 20U (the surface at the source electrode 12 side) of the semiconductor layer 20. The n-type impurity concentration (atoms/cm³) in the source region 23 is greater than the n-type impurity concentration in the drift region 21.

For example, the drift region 21 and the drain region 24 are located over the cell region RC and the peripheral region RE; and the base region 22 and the source region 23 are located in the cell region RC.

For example, as illustrated in FIG. 4, multiple FP trenches TR1 (first trenches) and a gate trench TR2 (a second trench) are provided in the upper surface 20U of the semiconductor layer 20.

The FP trench TR1 extends from the upper surface 20U to the drift region 21 in the Z-direction. A FP insulating part 41 (a first insulating part) and a FP electrode 31 (a third electrode) are located inside the FP trench TR1. The FP insulating part 41 covers the inner wall (the side surface and the bottom surface) of the FP trench TR1. The FP insulating part 41 contacts the drift region 21 and the base region 22.

The FP electrode 31 acts as a field plate. The FP electrode 31 is positioned at the inner side of the FP insulating part 41 inside the FP trench TR1. In other words, the FP insulating part 41 is located between the FP electrode 31 and the semiconductor layer 20. The lower surface and side surface of the FP electrode 31 contact the FP insulating part 41. The FP electrode 31 is insulated from the semiconductor layer 20 by the FP insulating part 41. The FP electrode 31 includes a part arranged with a portion of the drift region 21 in directions in the X-Y plane. In other words, the FP electrode 31 faces a portion of the drift region 21 via the FP insulating part 41.

The gate trench TR2 includes a part positioned between two mutually-adjacent FP trenches TR1 (FP trenches TR1 that are most proximate to each other among the multiple FP trenches TR1). The gate trench TR2 extends from the upper surface 20U of the semiconductor layer 20 to the drift region 21 in the Z-direction. The gate trench TR2 is shallower than the FP trench TR1.

A gate insulating part 42 (a second insulating part) and a gate electrode 32 (a fourth electrode) are located inside the gate trench TR2. The gate insulating part 42 covers the inner wall (the side surface and the bottom surface) of the gate trench TR2. The gate insulating part 42 contacts the drift region 21, the base region 22, and the source region 23.

The gate electrode 32 is positioned at the inner side of the gate insulating part 42 inside the gate trench TR2. In other words, the gate insulating part 42 is located between the gate electrode 32 and the semiconductor layer 20. The lower surface and side surface of the gate electrode 32 contact the gate insulating part 42. The gate electrode 32 is insulated from the semiconductor layer 20 by the gate insulating part 42. The gate electrode 32 includes a part arranged with a portion of the drift region 21, the base region 22, and a portion of the source region 23 in directions in the X-Y plane. In other words, the gate electrode 32 faces the drift region 21, the base region 22, and the source region 23 via the gate insulating part 42. The FP electrode 31 extends to a deeper position than the gate electrode 32.

For example, as illustrated in FIG. 4, an insulating layer 51 that extends along the X-Y plane is located on the upper surface 20U of the semiconductor layer 20. A gate conductive layer 70 (a first conductive layer) and an insulating layer 52 are located on the insulating layer 51. The gate conductive layer 70 is positioned between the insulating layer 51 and the insulating layer 52. The source electrode 12 is located on the insulating layer 52.

The gate conductive layer 70 is positioned above the gate trench TR2 and the gate electrode 32. A portion of the gate conductive layer 70 is positioned directly above the gate electrode 32 inside the cell region RC. For example, as illustrated in FIG. 5, the gate conductive layer 70 is electrically connected with the gate electrode 32 by a gate contact 37 (a first contact). The gate contact 37 extends through the insulating layer 51 and is positioned between the gate electrode 32 and the gate conductive layer 70. That is, the gate contact 37 is located inside a contact hole that extends through the insulating layer 51. The gate contact 37 contacts the upper surface of the gate electrode 32 and the lower surface of the gate conductive layer 70.

The side surface and upper surface of the gate conductive layer 70 are covered with the insulating layer 52. The gate conductive layer 70 is insulated from the source electrode 12 by the insulating layer 52.

As illustrated in FIG. 5, a source conductive layer 35 (a second conductive layer) is located on the FP electrode 31 and the base region 22. The source conductive layer 35 electrically connects the FP electrode 31 and the source region 23. The source conductive layer 35 extends along the X-Y plane and contacts the upper surface of the FP electrode 31, the upper surface of the FP insulating part 41, and the upper surface of the base region 22.

More specifically, the source conductive layer 35 includes a central part 35a positioned at the center of the source conductive layer 35 in the X-Y plane, and an outer part 35b positioned further outward than the central part 35a. The source region 23 (and a portion of the base region 22) are located between the outer part 35b and the gate trench TR2. The outer part 35b contacts the source region 23 and the base region 22. The central part 35a covers and contacts the entire upper surface of the FP electrode 31. An upper end portion 41a of the FP insulating part 41 is positioned between the outer part 35b and the central part 35a. The entire upper surface of the FP insulating part 41 (the upper end portion 41a) is covered with the source conductive layer 35.

The upper surface of the source conductive layer 35 is positioned higher than the upper end of the gate electrode 32. The lower surface of the source conductive layer 35 is positioned higher than the lower end of the gate electrode 32.

The source conductive layer 35 is a conductive layer that is separate from the gate conductive layer 70 and the source electrode 12. For example, the insulating layer 51 is located on the source conductive layer 35. That is, the insulating layer 51 is located between the source conductive layer 35 and the gate conductive layer 70; and the source conductive layer 35 is insulated from the gate conductive layer 70. The source conductive layer 35 is positioned below the insulating layers 51 and 52, which are below the source electrode 12.

A source contact 36 (a second contact) that extends through the insulating layers 51 and 52 is located between the source electrode 12 and the source conductive layer 35. That is, the source contact 36 is located inside a contact hole that extends through the insulating layers 51 and 52. The source contact 36 contacts the lower surface of the source electrode 12 and the center of the upper surface of the source conductive layer 35 (the central part 35a). As a result, the source contact 36 electrically connects the source electrode 12 and the source conductive layer 35.

The source contact 36 is positioned directly above the FP electrode 31. The source conductive layer 35 (the central part 35a) is positioned between the FP electrode 31 and the source contact 36 and electrically connects the FP electrode 31 and the source contact 36.

As illustrated in FIG. 3, the source region 23 (and a portion of the base region 22) surround the outer perimeter surface of the outer part 35b of the source conductive layer 35 in the X-Y plane and contact the outer perimeter surface of the outer part 35b. The outer part 35b surrounds the outer perimeter surface of the upper end portion 41a of the FP insulating part 41 in the X-Y plane and contacts the outer perimeter surface of the upper end portion 41a. The upper end portion 41a surrounds the outer perimeter of the central part 35a of the source region 23 and contacts the central part 35a.

In FIG. 2, the positions of the FP electrode 31, the FP insulating part 41, the FP trench TR1, the source conductive layer 35, and the gate trench TR2 when viewed in plan from above are illustrated by broken lines. For example, as illustrated in FIG. 2, the multiple FP trenches TR1 are arranged in the X-Y plane in the cell region RC. More specifically, the multiple FP trenches TR1 are arranged in a first arrangement direction D1 and a second arrangement direction D2. The first arrangement direction D1 is the direction of the shortest line connecting one FP trench TR1 and the FP trench TR1 most proximate to the one FP trench TR1. The multiple FP electrodes 31 (the FP trenches TR1) are positioned at the intersections of a lattice shape or a mesh shape in which lines extending in the first arrangement direction D1 and lines extending in the second arrangement direction D2 cross when viewed in plan. In the example, the first arrangement direction D1 is the X-direction; and the second arrangement direction D2 is the Y-direction. Accordingly, the multiple FP electrodes 31 are positioned at vertices of squares when viewed in plan. According to the embodiment, the first arrangement direction D1 and the second arrangement direction D2 are not necessarily orthogonal.

For example, the planar shapes of the FP electrode 31 and the FP insulating part 41 are circular. The planar shapes of the FP electrode 31 and the FP insulating part 41 may be a regular polygon such as a square, a regular hexagon, etc. A regular polygon includes a regular polygon with rounded corners. The FP electrodes 31 are located at the centers of the FP trenches TR1. The source contacts 36 have cylindrical shapes positioned at the centers of the FP electrodes 31.

As illustrated in FIG. 3, the gate trench TR2 includes a first extension part 61, a second extension part 62, and a wide part 65 in the cell region RC.

The first extension part 61 is positioned between two FP trenches TR1 adjacent to each other in the first arrangement direction D1; and the first extension part 61 extends in a direction perpendicular to the first arrangement direction D1. For example, the first extension part 61 has a constant width W61 (the length in the direction perpendicular to the first arrangement direction D1).

The second extension part 62 is positioned between two FP trenches TR1 adjacent to each other in the second arrangement direction D2; and the second extension part 62 extends in a direction perpendicular to the second arrangement direction D2. For example, the second extension part 62 has a constant width W62 (the length in the direction perpendicular to the second arrangement direction D2). The width W62 may be equal to the width W61.

The wide part 65 is arranged with the first extension part 61 in the Y-direction (a direction perpendicular to the first arrangement direction D1); and the wide part 65 is continuous with the first extension part 61. The wide part 65 is a part at which the width of the gate trench TR2 is wider than the first extension part 61 or the second extension part 62. In other words, a width W65 (the length in the direction perpendicular to the first arrangement direction D1) of the wide part 65 is greater than the width W61 of the first extension part 61. The width W65 of the wide part 65 is greater than the width W62 of the second extension part 62. The width in the second arrangement direction D2 of the wide part 65 may be equal to the width W65 in the first arrangement direction D1. The wide part 65 and the first extension part 61 are alternately arranged in the Y-direction (the direction perpendicular to the first arrangement direction D1).

The wide part 65 connects the end of the first extension part 61 and the end of the second extension part 62. For example, the planar shape of the gate trench TR2 is a mesh shape. In the example, the gate trench TR2 has a lattice shape in which a part extending in the first arrangement direction D1 and a part extending in the second arrangement direction D2 cross at the wide part 65. In other words, the wide parts 65 are positioned at the vertices of the square; and two first extension parts 61 and two second extension parts 62 are positioned at the four sides of the square. One FP trench TR1 is located inside the square; and the FP electrode 31 is positioned at the center of the square.

For example, the width of the wide part 65 gradually widens continuously from the first extension part 61 or the second extension part 62. Accordingly, the planar shape of the region surrounded with the first extension part 61, the second extension part 62, and the wide part 65 is a polygon (in the example, a square) with rounded corners.

The thickness of the gate insulating part 42 inside the gate trench TR2 may be substantially constant when viewed in plan. The gate electrode 32 includes an extension part (a first extension part 321) that is located inside the first extension part 61 and extends similarly to the first extension part 61, an extension part (a second extension part 322) that is located inside the second extension part 62 and extends similarly to the second extension part 62, and a part that is located inside the wide part 65. Similarly to the gate trench TR2, the gate electrode 32 has a mesh shape or a lattice shape. The gate electrode 32 inside the wide part 65 may be a wide part 325 that is wider than the gate electrode 32 inside the first extension part 61 or inside the second extension part 62. By setting the gate trench TR2 and the gate electrode 32 inside the gate trench TR2 to have a mesh shape or a lattice shape, a large region that operates as a transistor can be ensured.

The width of the gate trench TR2 (the width W61 of the first extension part 61 and the width W62 of the second extension part 62) may be less than the width (the length in the first arrangement direction D1 or the second arrangement direction D2) of the FP trench TR1. The width of the gate electrode 32 inside the first extension part 61 or the second extension part 62 may be less than the width of the FP electrode 31.

As illustrated in FIG. 3, the planar shape of the gate contact 37 is, for example, a circular cylindrical shape. The gate contact 37 is positioned at the center of the wide part 65 of the gate trench TR2. The gate contact 37 may be located only at the wide part 65, and may not be located at the first extension part 61 or the second extension part 62. The diameter of the gate contact 37 may be greater than the width W61 of the first extension part 61 or the width W62 of the second extension part 62.

As illustrated in FIG. 2, the gate conductive layer 70 includes multiple first wiring parts 71. The first wiring part 71 extends along the first extension part 61 above the first extension part 61 of the gate trench TR2. For example, the first wiring parts 71 are positioned above the multiple first extension parts 61 and the multiple wide parts 65 and extend in the second arrangement direction D2. For example, the first wiring parts 71 are connected with the multiple gate contacts 37 positioned directly under the first wiring parts 71.

The gate conductive layer 70 also includes multiple second wiring parts 72. The second wiring part 72 extends along the second extension part 62 above the second extension part 62 of the gate trench TR2. In other words, in the example, the gate conductive layer 70 has a lattice shape in which the first wiring parts 71 and the second wiring parts 72 cross each other. For example, the gate conductive layer 70 overlaps the entire gate trench TR2 in the vertical direction. The gate contacts 37 are connected to intersection parts 75 between the first wiring parts 71 and the second wiring parts 72.

When viewed in plan, one FP electrode 31 is surrounded with a square formed of two adjacent first wiring parts 71 and two adjacent second wiring parts 72; and the source contact 36 is located at the center of the square.

The first wiring part 71 and the second wiring part 72 extend from the cell region RC to the peripheral region RE and are electrically connected with the gate wiring part 14 (see FIG. 1) positioned above the first wiring part 71 and the second wiring part 72 in the peripheral region RE.

Examples of materials of components of the semiconductor device 100 will now be described.

The semiconductor regions of the semiconductor layer 20 include silicon (Si), silicon carbide, gallium nitride, or gallium arsenide as a semiconductor material. When silicon is used as the semiconductor material, arsenic, phosphorus, or antimony can be used as an n-type impurity. Boron can be used as a p-type impurity. The semiconductor layer 20 is, for example, a semiconductor substrate such as a silicon substrate, etc.

The FP electrode 31 and the gate electrode 32 include a conductive material such as polysilicon, a metal, etc.

The FP insulating part 41, the gate insulating part 42, the insulating layer 51, and the insulating layer 52 include an insulating material such as silicon oxide, silicon nitride, etc.

The gate contact 37 and the source contact 36 include, for example, a metal such as W (tungsten), Ti (titanium), etc.

The drain electrode 11, the source electrode 12, the gate wiring part 14, and the gate pad 13 include a metal such as Al (aluminum), etc.

The gate conductive layer 70 includes at least one of polysilicon, a silicide, or a metal material. The source conductive layer 35 includes at least one of polysilicon, a silicide, or a metal material. The silicide includes at least one selected from the group consisting of Co (cobalt), W, Ti, and Ni (nickel). A metal silicide such as CoSi, WSi, TiSi, NiSi, or the like is used as the silicide. The metal material includes at least one selected from the group consisting of Ti, TiN (titanium nitride), W, Cu (copper), and Al. By using the metal material, a conductive layer having a lower resistance can be obtained. For example, the electrical resistivity of the gate conductive layer 70 or the source conductive layer 35 may be less than the electrical resistivity of the gate electrode 32 or the FP electrode 31. The gate conductive layer 70 and/or the source conductive layer 35 are easily formed by using polysilicon and/or a silicide.

Operations of the semiconductor device 100 will now be described.

A positive voltage is applied to the gate pad 13 in a state in which a positive voltage with respect to the source electrode 12 is applied to the drain electrode 11. As a result, the voltage is applied from the gate pad 13 to the gate electrode 32 via the gate wiring part 14, the gate conductive layer 70, and the gate contact 37. When a voltage that is greater than a threshold is applied to the gate electrode 32, an inversion layer is formed in the base region 22; and the transistor is switched on. In other words, an on-current flows from the drain electrode 11 to the source electrode 12 via the drift region 21, the base region 22, the source region 23, the source conductive layer 35, and the source contact 36. When the voltage of the gate pad 13 is reduced and the voltage of the gate electrode 32 reaches or drops below the threshold, the transistor is switched off, and the on-current does not flow.

In the semiconductor device 100 according to the embodiment as described above, the gate conductive layer 70 that is electrically connected with the gate electrode 32 is located above the gate electrode 32 inside the cell region RC. The gate resistance of the semiconductor device 100 can be reduced thereby.

For example, as a semiconductor device of a reference example, a configuration may be considered in which the gate wiring part 14 and the gate electrode 32 are connected in the peripheral region RE without including the gate conductive layer 70 and the gate contact 37 inside the cell region RC. In contrast, according to the embodiment, by including the gate conductive layer 70, for example, the current inside the cell region RC flows through a path in which the gate conductive layer 70 and the gate electrode 32 are connected in parallel. As a result, the gate resistance of the embodiment can be reduced compared to the reference example.

A reference example may be considered in which efforts are made in the chip layout design to reduce the gate resistance by increasing the gate wiring parts 14. When, however, the gate wiring parts 14 are increased, the effective device area for the same chip size is reduced, and the area efficiency degrades. Also, it may be considered to reduce the gate resistance by using a metal gate in which the gate electrode is formed of a metal material. However, in the case of a metal gate, there is a risk that characteristics such as breakdown voltage, leakage current, defect density, etc., may be degraded by damage of the gate insulating film, etc., in the manufacturing processes. There are cases where the manufacturing processes become complex for a metal gate.

In contrast, according to the embodiment, the gate resistance can be reduced by including the gate conductive layer 70 as described above. For example, by using polysilicon as the material of the gate electrode 32 and by including the gate conductive layer 70, the gate resistance can be reduced while avoiding characteristic degradation and/or higher complexity of the manufacturing processes due to the metal gate. However, according to the embodiment, a metal material also can be used as the gate electrode 32.

The gate resistance can be reduced by widening the gate electrode 32. When, however, the width of the gate electrode 32 is increased, there are cases where the capacitance between the gate electrode 32 and the drain electrode 11 or the like is increased, and the reverse transfer capacitance of the transistor is increased. For example, in a structure in which the gate electrode 32 and the FP electrode 31 are located in separate trenches, there are cases where the reverse transfer capacitance is easily increased by widening the gate electrode 32 compared to a configuration in which the gate electrode 32 and the FP electrode are located in the same trench. In contrast, in a configuration in which the gate electrode 32 and the FP electrode 31 are located in separate trenches, the gate resistance can be reduced while suppressing an increase of the reverse transfer capacitance by including the gate conductive layer 70.

As described with reference to FIG. 4 or FIG. 5, the source electrode 12 is located on the insulating layer 52 on the gate conductive layer 70. Thus, by providing the gate conductive layer 70 and the source electrode 12 in separate layers, the gate conductive layer 70 can extend more widely inside the cell region RC.

The gate contact 37 is located at the wide part 65 of the gate trench TR2. As a result, for example, even when misalignment occurs due to fluctuation of the manufacturing processes, the gate contact 37 can be more reliably connected to the gate electrode 32. For example, a width W37 (the diameter) of the gate contact 37 may be greater than the width W61 of the first extension part 61 of the gate trench TR2. The electrical resistance can be further reduced when the gate contact 37 is wide.

As illustrated in FIG. 3, one wide part 65 is surrounded with the four FP trenches TR1 among the multiple FP trenches TR1 most proximate to the one wide part 65. In other words, the wide part 65 is positioned equidistant from the multiple FP electrodes 31 (or source contacts 36) surrounding the wide part 65. The gate contact 37 that is positioned at the center of the wide part 65 is positioned equidistant from the multiple FP electrodes 31 (or source contacts 36) surrounding the gate contact 37. That is, the gate contact 37 is located at a position at which the distances from the FP electrodes or the source contacts 36 are maxima. As a result, space to provide the wide part 65 and the gate contact 37 can be ensured. Interference of the arrangement of the gate contact 37 and the source contact 36 can be suppressed.

The source conductive layer 35 that electrically connects the source region 23 and the FP electrode 31 is provided as a separate layer from the source electrode 12. By including the source conductive layer 35, interference between the gate conductive layer 70 and the contact connecting the source region 23 and the source electrode 12 can be suppressed.

For example, as illustrated in FIG. 4 or FIG. 5, the source conductive layer 35 extends laterally from the source region 23 and is connected to the source contact 36 directly above the FP electrode 31. The source region 23 and the source electrode 12 can be electrically connected thereby, and so the source contact 36 may not be located directly above the source region 23. Thus, the source contact 36 can be located away from the position of the gate conductive layer 70; and interference between the source contact 36 and the gate conductive layer 70 can be suppressed.

In the example as illustrated in FIG. 3, the planar shape of the region surrounded with the gate trench TR2 is a square with rounded corners; and the planar shape of the source conductive layer 35 also is a square with rounded corners. In other words, when viewed in plan, the outer edge of the source conductive layer 35 extends along the gate trench TR2 (the gate electrode 32) so that the distance from the gate trench TR2 (the gate electrode 32) is constant. In other words, the width of the source region 23 is substantially constant. Bias of the transistor characteristics in the plane can be suppressed.

As described with reference to FIG. 2, the gate conductive layer 70 includes the first wiring part 71 that is connected with the multiple gate contacts 37 positioned directly under the gate conductive layer 70. By using the first wiring part 71, the gate conductive layer 70 is drawn out to the peripheral region RE while avoiding the source contact 36. In the example, the gate conductive layer 70 has a lattice shape in which the first wiring part 71 and the second wiring part 72 that extend along the gate trench TR2 and the gate electrode 32 cross. As a result, the gate resistance can be further reduced, and the gate conductive layer 70 can be drawn out in two directions.

For example, as illustrated in FIG. 2, a width W71 (the length in a direction perpendicular to the second arrangement direction D2) of the first wiring part 71 is greater than the width W61 of the first extension part 61 of the gate trench TR2 (see FIG. 3). The width W71 of the first wiring part 71 may be greater than the width W65 of the wide part 65 (see FIG. 3). For example, the first wiring part 71 covers all of the multiple first extension parts 61. The first wiring part 71 (the intersection part 75) covers all of the multiple wide parts 65 from above. Thus, by widening the gate conductive layer 70, for example, the gate conductive layer 70 can be more reliably located on the gate contact 37 even when there is fluctuation of the manufacturing processes.

For example, the gate conductive layer 70 (the end portion of the first wiring part 71 and/or the end portion of the second wiring part 72) may overlap the outer part 35b of the source conductive layer 35 and the end portion of the FP insulating part 41 in the vertical direction.

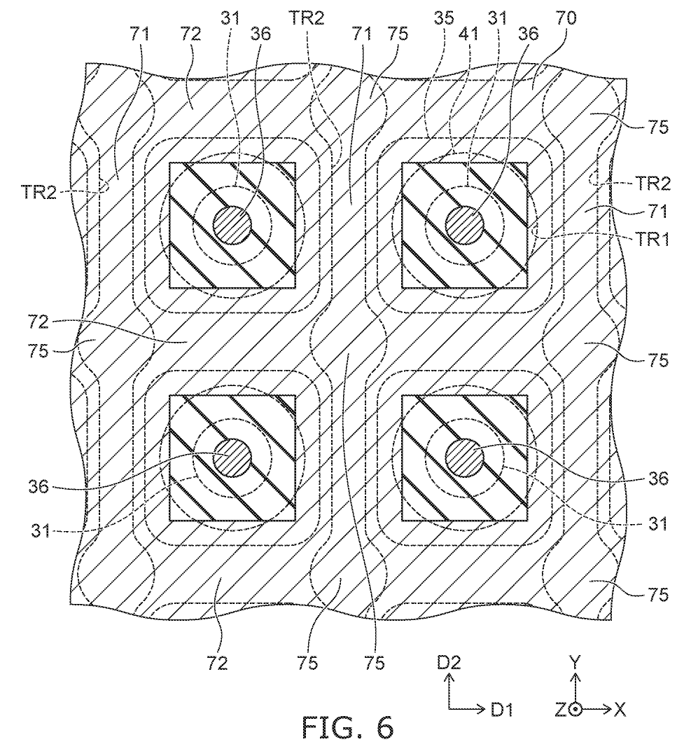

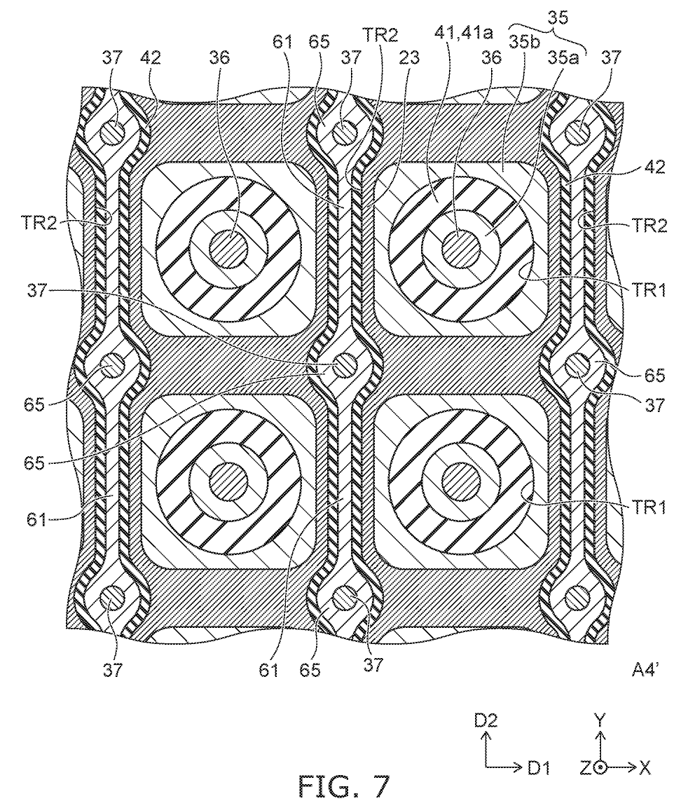

FIGS. 6 and 7 are schematic views illustrating a semiconductor device according to a modification of the embodiment.

FIG. 6 illustrates a planar layout of the semiconductor device of the modification similarly to FIG. 2.

FIG. 7 illustrates the planar layout of the semiconductor device of the modification similarly to FIG. 3.

The second extension part 62 of the gate trench TR2, the gate electrode 32 inside the second extension part 62, and the gate insulating part 42 inside the second extension part 62 of the semiconductor device 100 described with reference to FIGS. 1 to 5 are omitted from the configuration according to the modification.

In other words, in the example, the multiple gate trenches TR2 are arranged in a stripe configuration. The multiple gate trenches TR2 are arranged in the first arrangement direction D1. The gate trenches TR2 extend in the second arrangement direction D2. Each gate trench TR2 has a shape in which the first extension part 61 and the wide part 65 are alternately arranged in the second arrangement direction D2. The multiple FP electrodes 31 are arranged in the second arrangement direction D2 between two adjacent gate trenches TR2.

Thus, when the gate trench TR2 and the gate electrode 32 have a stripe configuration, compared to a lattice shape, for example, the electrical capacitance between the gate electrode 32 and the drain electrode 11 can be reduced, and the reverse transfer capacitance of the transistor can be reduced.

The gate contact 37 and the gate conductive layer 70 are included in the example as well. For example, as illustrated in FIG. 6, in the example as well, the gate conductive layer 70 may have a lattice shape including the first wiring part 71 and the second wiring part 72. The first wiring part 71 extends along the gate trench above the gate trench TR2. The gate contact 37 is connected to the intersection part 75 between the first wiring part 71 and the second wiring part 72. Similarly to the semiconductor device 100 described with reference to FIGS. 1 to 5, the gate resistance can be suppressed. Also, the interference between the gate conductive layer 70 and the source contact 36 can be suppressed by the source conductive layer 35.

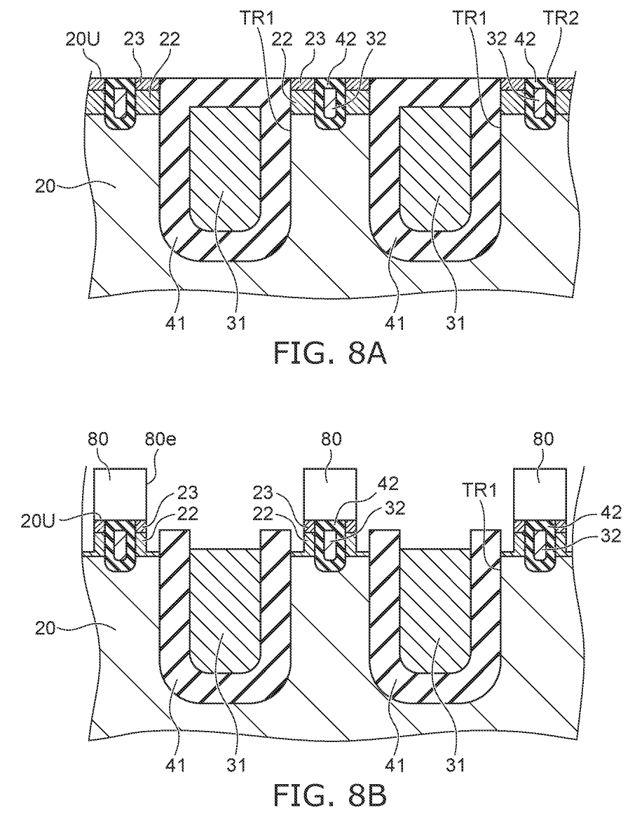

FIGS. 8A, 8B, 9A, 9B, and 10 are schematic cross-sectional views illustrating a method for manufacturing the semiconductor device according to the embodiment.

As illustrated in FIG. 8A, for example, the FP trench TR1 and the gate trench TR2 are provided in the upper surface 20U of the semiconductor layer 20 by RIE (reactive ion etching). The FP insulating part 41 is formed inside the FP trench TR1; and the FP electrode 31 is formed at the inner side of the FP insulating part 41. The gate insulating part 42 is formed inside the gate trench TR2; and the gate electrode 32 is formed at the inner side of the gate insulating part 42. The base region 22 and/or the source region 23 are formed by ion implantation before forming (or after forming) the FP trench TR1 and the gate trench TR2.

Subsequently, as illustrated in FIG. 8B, a resist 80 is formed on the semiconductor layer 20. An opening 80e is formed in the resist 80 above the FP trench TR1 by photolithography. Then, portions of the FP insulating part 41 and the semiconductor layer 20 at the upper surface 20U side are removed by performing RIE using the resist 80 as a mask. As a result, the upper surface of the FP electrode 31, the base region 22, and the source region 23 are exposed. Subsequently, the resist 80 is removed.

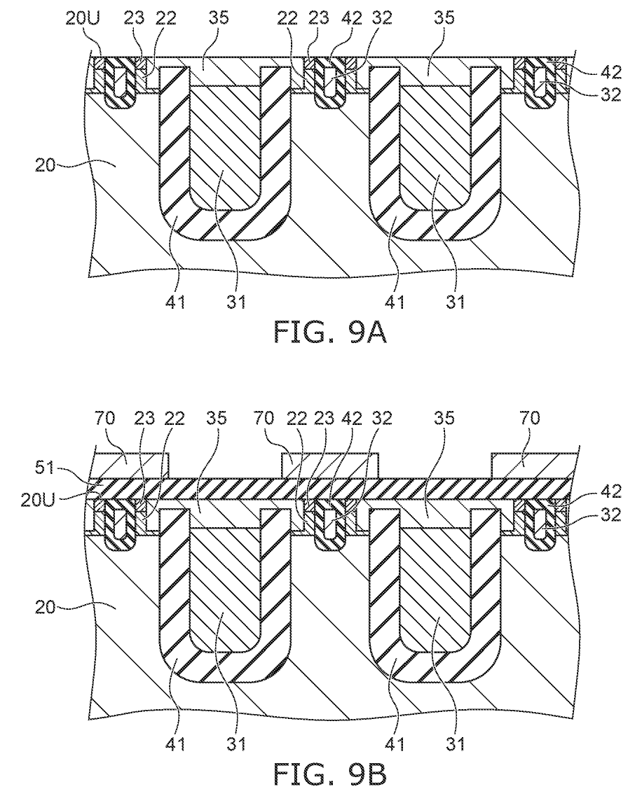

Subsequently, as illustrated in FIG. 9A, the source conductive layer 35 is formed on the upper surface of the FP electrode 31, the base region 22, the source region 23, and the FP insulating part 41 exposed at the upper surface 20U side. For example, the source conductive layer 35 is formed at the upper surface 20U side by depositing a stacked film of Ti, TiN, and W and by planarizing by CMP (Chemical Mechanical Polishing). The upper surfaces of the gate insulating part 42, the source region 23, and the source conductive layer 35 are exposed at the upper surface 20U side.

Subsequently, as illustrated in FIG. 9B, the insulating layer 51 is formed on the gate insulating part 42, the source region 23, and the source conductive layer 35. The gate contact 37 that extends through the insulating layer 51 directly above the gate electrode 32 and connects with the gate electrode 32 (not illustrated in FIG. 9B) is formed. Then, the gate conductive layer 70 that is connected with the gate contact 37 is formed on the insulating layer 51. For example, the gate conductive layer 70 is formed by depositing a metal film such as W or the like on the insulating layer 51 and by using RIE to remove a portion of the metal film directly above the FP electrode 31.

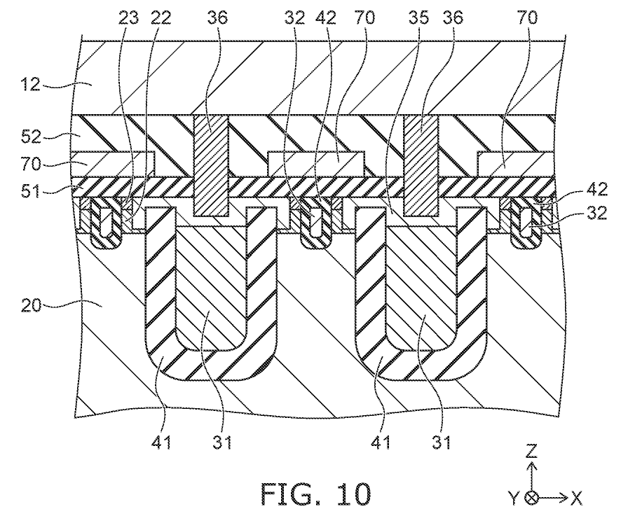

Subsequently, as illustrated in FIG. 10, the insulating layer 52 is formed on the insulating layer 51 and the gate conductive layer 70. The source contact 36 that extends through the insulating layers 51 and 52 and is connected with the source conductive layer 35 is formed directly above the FP electrode 31. Then, the source electrode 12 that is connected with the source contact 36 is formed on the insulating layer 52.

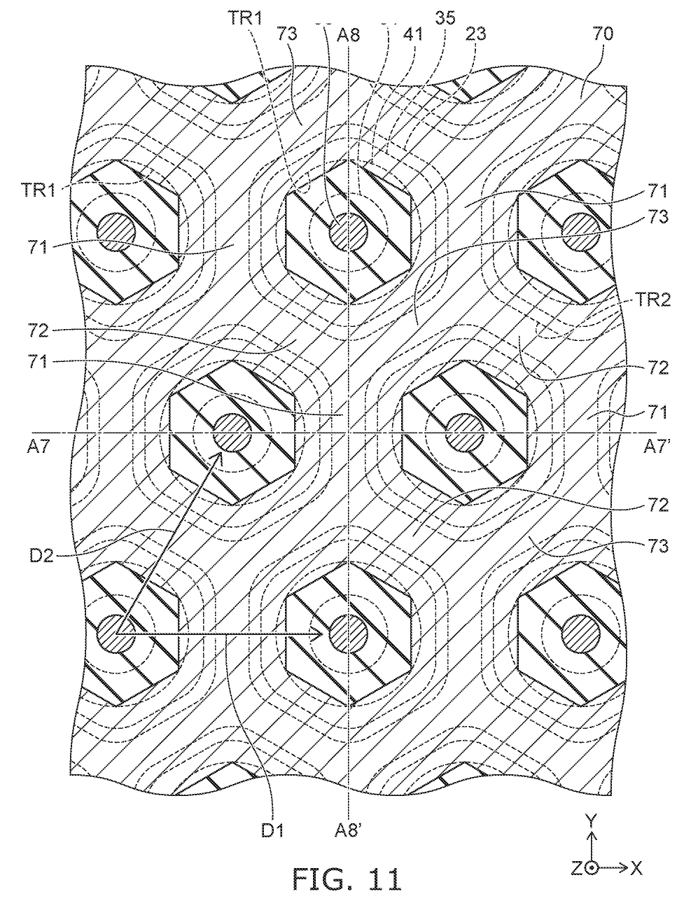

FIGS. 11 to 14 are schematic views illustrating another semiconductor device according to the embodiment.

Although not illustrated, similarly to FIG. 1 above, the semiconductor device also includes the cell region RC in which the source electrode 12 is located, and the peripheral region RE in which the gate wiring part 14 and the gate pad 13 are located.

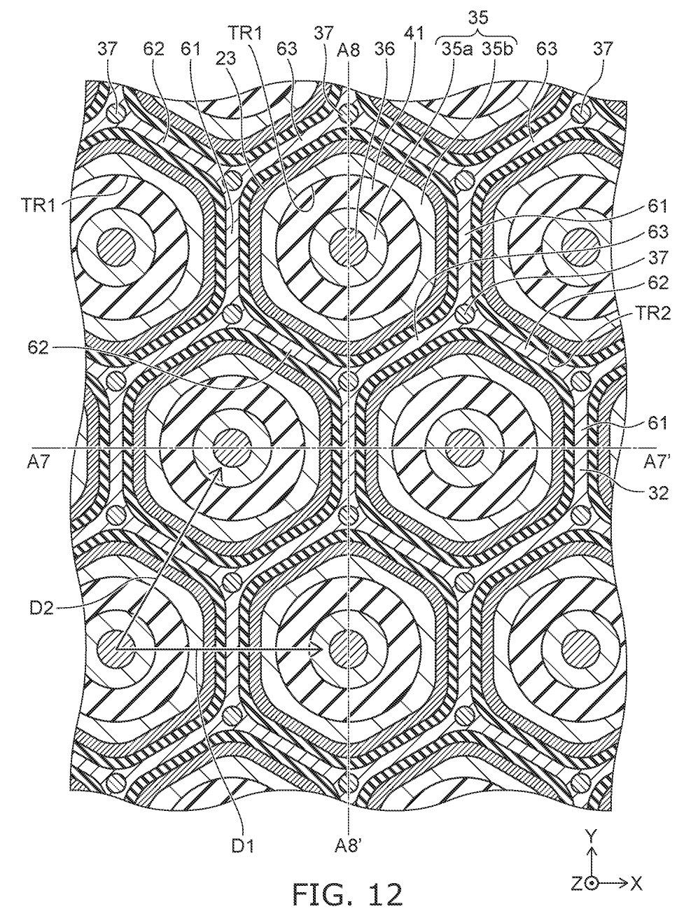

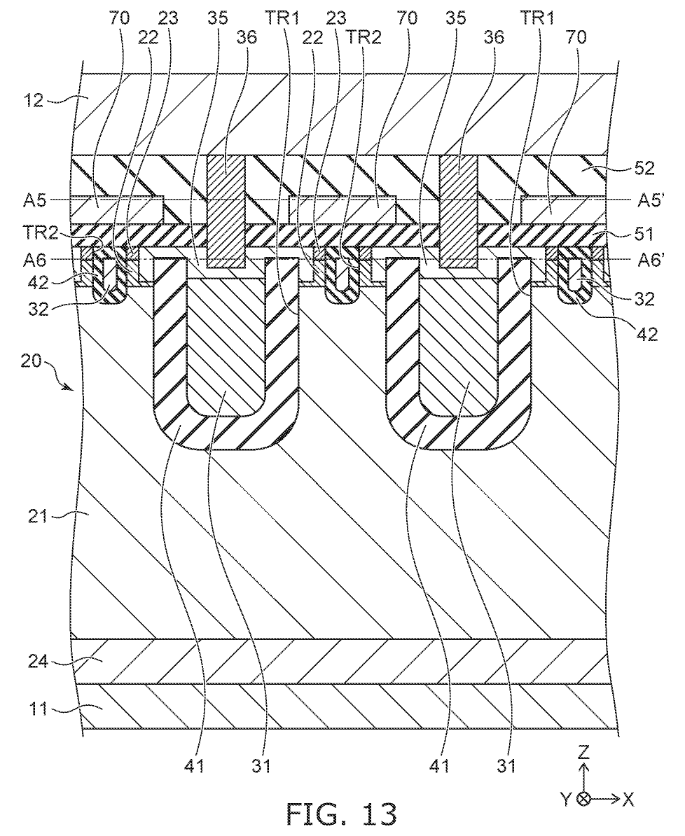

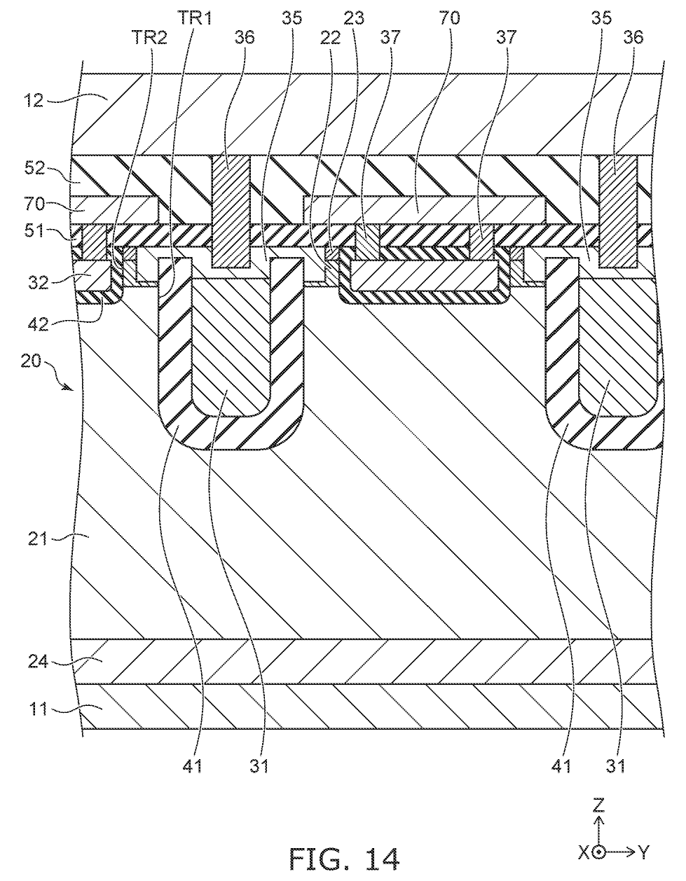

FIGS. 11 to 14 illustrate the structure inside the cell region RC. FIGS. 11 and 12 illustrate the planar layout. The hatching of FIG. 11 corresponds to a cross section along line A5-A5ʹ shown in FIG. 13; and the hatching of FIG. 12 corresponds to a cross section along line A6-A6ʹ shown in FIG. 13. FIG. 13 illustrates a cross section along line A7-A7ʹ shown in FIGS. 11 and 12. FIG. 14 illustrates a cross section along line A8-A8ʹ shown in FIGS. 11 and 12.

In the cell region RC as illustrated in FIG. 11, the multiple FP trenches TR1 are arranged in the first and second arrangement directions D1 and D2 in the X-Y plane. In the example, the first arrangement direction D1 is the X-direction. The second arrangement direction D2 is a direction oblique to the first arrangement direction D1. For example, the angle between the first arrangement direction D1 and the second arrangement direction D2 is 60°. In the example, the multiple FP electrodes 31 are positioned at vertices of triangles (e.g., equilateral triangles) when viewed in plan.

As illustrated in FIG. 12, the gate trench TR2 includes the first extension part 61, the second extension part 62, and a third extension part 63. The first extension part 61 extends in the Y-direction (the direction perpendicular to the first arrangement direction D1). The second extension part 62 extends in the direction perpendicular to the second arrangement direction D2. The third extension part 63 extends in a different direction from the first and second extension parts 61 and 62.

The planar shape of the gate trench TR2 is a mesh shape in which hexagons (e.g., regular hexagons) are arranged. In other words, two first extension parts 61, two second extension parts 62, and two third extension parts 63 are positioned at the six sides of the hexagon. The first extension part 61, the second extension part 62, and the third extension part 63 are connected at each vertex of the hexagon. One FP trench TR1 is located inside the hexagon; and the FP electrode 31 is positioned at the center of the hexagon. The hexagon that is formed of the gate trench TR2 may be a hexagon with rounded corners (vertices). In such a case, the vertices of the hexagon (the connection parts of the three extension parts) are wide parts that are wider than the extension parts. For example, the planar shape of the region surrounded with the first extension part 61, the second extension part 62, the third extension part 63, and the wide part is a regular hexagon with rounded corners.

The gate contact 37 is located at the connection part between the first extension part 61, the second extension part 62, and the third extension part 63. In other words, the gate contact 37 is positioned at the vertex of the hexagon. Similarly to the gate trench TR2, the gate electrode 32 has a mesh shape in which the hexagons are repeated.

As illustrated in FIG. 11, the gate conductive layer 70 includes the first wiring part 71, the second wiring part 72, and a third wiring part 73. The first wiring part 71 extends along the first extension part 61 above the first extension part 61 of the gate trench TR2. The second wiring part 72 extends along the second extension part 62 above the second extension part 62 of the gate trench TR2. The third wiring part 73 extends along the third extension part 63 above the third extension part 63 of the gate trench TR2.

In other words, the planar shape of the gate conductive layer 70 is a mesh shape in which the hexagons are arranged. Two first wiring parts 71, two second wiring parts 72, and two third wiring parts 73 are positioned at the six sides of the hexagon. The gate contact 37 is connected to the intersection part between the first wiring part 71, the second wiring part 72, and the third wiring part 73, that is, the vertex of the hexagon.

Thus, the multiple FP electrodes 31 may be located on triangles. In the example as well, similarly to the semiconductor device described above, the gate resistance can be reduced by including the gate conductive layer 70. In such a case, by including the source conductive layer 35, a contact that connects the source region 23 and the source electrode 12 can be formed while avoiding the position of the gate conductive layer 70.

According to embodiments, a semiconductor device can be provided in which the gate resistance can be reduced.

In this specification, being "electrically connected" includes not only the case of being connected in direct contact, but also the case of being connected via another conductive member, etc.

The relative levels of the impurity concentrations between the semiconductor regions can be confirmed using, for example, a SCM (scanning capacitance microscope). The carrier concentration in each semiconductor region can be considered to be equal to the activated impurity concentration in each semiconductor region. Accordingly, the relative levels of the carrier concentrations between the semiconductor regions also can be confirmed using SCM. Also, the impurity concentration in each semiconductor region can be measured by, for example, SIMS (secondary ion mass spectrometry).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor device, comprising:
a first electrode;
a second electrode positioned above the first electrode;
a semiconductor layer located between the first electrode and the second electrode, the semiconductor layer including
a first semiconductor region of a first conductivity type,
a second semiconductor region located on the first semiconductor region, the second semiconductor region being of a second conductivity type, and
a third semiconductor region located on the second semiconductor region, the third semiconductor region being electrically connected with the second electrode, the third semiconductor region being of the first conductivity type;
a plurality of third electrodes arranged in a cell region in which the second electrode is located, the plurality of third electrodes facing the first semiconductor region via a first insulating part;
a fourth electrode including a part positioned between two mutually-adjacent third electrodes among the plurality of third electrodes, the fourth electrode including a first extension part and a wide part, the first extension part being positioned in the cell region, the wide part being positioned in the cell region and being wider than the first extension part, the fourth electrode facing the second semiconductor region via a second insulating part;
a first contact positioned above the fourth electrode, the first contact being connected with the wide part of the fourth electrode; and
a first conductive layer positioned above the fourth electrode, the first conductive layer being connected with the fourth electrode by the first contact.

2. The device according to claim 1, wherein
the second electrode is located on an insulating layer located on the first conductive layer.

3. The device according to claim 1, further comprising:
an insulating layer located on the semiconductor layer; and
a second conductive layer positioned below the insulating layer, the second conductive layer being insulated from the first conductive layer and electrically connected with the second electrode, the second conductive layer electrically connecting the third semiconductor region and the third electrode.

4. The device according to claim 3, wherein
an outer edge of the second conductive layer extends along the fourth electrode so that a distance from the fourth electrode to the outer edge of the second conductive layer is constant.

5. The device according to claim 3, further comprising:
a second contact positioned directly above the third electrode,
the second contact extending through the insulating layer,
the second contact electrically connecting the second conductive layer and the second electrode.

6. The device according to claim 1, wherein
the first contact is positioned equidistant from a plurality of the third electrodes surrounding the first contact.

7. The device according to claim 1, wherein
the plurality of third electrodes is arranged in a first arrangement direction and a second arrangement direction,
the first arrangement direction and the second arrangement direction cross each other,
the first extension part is positioned between two third electrodes among the plurality of third electrodes adjacent to each other in the first arrangement direction,
the fourth electrode further includes a second extension part positioned between two third electrodes among the plurality of third electrodes adjacent to each other in the second arrangement direction, and
the wide part connects an end of the first extension part and an end of the second extension part.

8. The device according to claim 7, wherein
the second arrangement direction is orthogonal to the first arrangement direction, and
the fourth electrode has a lattice shape.

9. The device according to claim 7, wherein
the first conductive layer includes a first wiring part extending in the second arrangement direction, and
the first wiring part is connected with a plurality of the first contacts positioned directly under the first wiring part.

10. The device according to claim 8, wherein
the first conductive layer has a lattice shape in which a first wiring part and a second wiring part cross each other,
the first wiring part extends along the first extension part above the first extension part,
the second wiring part extends along the second extension part above the second extension part, and
the first contact is connected to an intersection part between the first wiring part and the second wiring part.

11. The device according to claim 1, wherein
a plurality of the fourth electrodes is arranged in a stripe configuration.

12. The device according to claim 11, wherein
the first conductive layer includes a first wiring part and a second wiring part,
the first wiring part extends along the fourth electrode above the fourth electrode,
the second wiring part crosses the first wiring part, and
the first contact is connected to an intersection part between the first wiring part and the second wiring part.

13. The device according to claim 9, wherein
a width of the first wiring part is greater than a width of the first extension part of the fourth electrode.

14. The device according to claim 3, wherein
a portion of the first conductive layer overlaps a portion of the second conductive layer in a vertical direction.

15. The device according to claim 1, wherein
the plurality of third electrodes is positioned at vertices of squares or at vertices of equilateral triangles.

16. The device according to claim 1, wherein
the first conductive layer includes at least one of polysilicon, a silicide, or a metal material,
the silicide includes at least one selected from the group consisting of Co, W, Ti, and Ni, and
the metal material includes at least one selected from the group consisting of Ti, TiN, W, Cu, and Al.

17. The device according to claim 3, wherein
the second conductive layer includes at least one of polysilicon, a silicide, or a metal material,
the silicide includes at least one selected from the group consisting of Co, W, Ti, and Ni, and
the metal material includes at least one selected from the group consisting of Ti, TiN, W, Cu, and Al.

18. The device according to claim 3, wherein
the second conductive layer contacts the second semiconductor region, the third semiconductor region, and the third electrode.

19. The device according to claim 1, wherein
the second semiconductor region is positioned between the third electrode and the fourth electrode.

20. A semiconductor device, comprising:
a first electrode;
a second electrode positioned above the first electrode;
a semiconductor layer located between the first electrode and the second electrode, the semiconductor layer including
a first semiconductor region of a first conductivity type,
a second semiconductor region located on the first semiconductor region, the second semiconductor region being of a second conductivity type, and
a third semiconductor region located on the second semiconductor region, the third semiconductor region being electrically connected with the second electrode, the third semiconductor region being of the first conductivity type;
a plurality of third electrodes arranged in a cell region in which the second electrode is located, the plurality of third electrodes facing the first semiconductor region via a first insulating part;
a fourth electrode including a part positioned between two mutually-adjacent third electrodes among the plurality of third electrodes, the fourth electrode facing the second semiconductor region via a second insulating part;
a first conductive layer including a part positioned directly above the fourth electrode in the cell region, the first conductive layer being electrically connected with the fourth electrode by a first contact;
a second conductive layer insulated from the first conductive layer and electrically connected with the second electrode, the second conductive layer electrically connecting the third semiconductor region and the third electrode; and
an insulating layer positioned above the second conductive layer and positioned below the second electrode.
